(19) United States
(12) Patent Application Publication
(10) Pub. No.: US 2024/0290781 A1
(43) Pub. Date: Aug. 29, 2024

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takahiro KATO, Yokohama Kanagawa (JP); Tatsunori Sakano, Shinagawa Tokyo (JP); Yusuke Kobayashi, Yokohama Kanagawa (JP); Ryohei Gejo, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/454,361

(22) Filed: Aug. 23, 2023

(30) Foreign Application Priority Data
Feb. 28, 2023 (JP) 2023-030171

(51) Int. Cl. H01L 27/06; H01L 29/739; H01L 29/861

(52) U.S. Cl. CPC H01L 27/0664; H01L 29/7397; H01L 29/8613

(57) ABSTRACT

A semiconductor device includes first and second electrodes, a first interconnect, a semiconductor layer, first and second control electrodes. The second electrode is disposed in an element region. The first interconnect is disposed in a first interconnect region. The semiconductor layer is provided between the first electrode and the second electrode and between the first electrode and the first interconnect. The semiconductor layer includes first to seventh semiconductor regions. The second semiconductor region is provided between the first electrode and the first semiconductor region. The first semiconductor region includes a first semiconductor portion disposed in the first interconnect region and a second semiconductor portion disposed in the element region. The seventh semiconductor region is disposed in the element region. The first control electrode is arranged with the first and second semiconductor regions. The second control electrode is arranged with the first, second and seventh semiconductor regions.

### CROSS-REFERENCE TO RELATED APPLICATIONS

This application is based upon and claims the benefit of priority from Japanese Patent Application No. 2023-030171, filed on Feb. 28, 2023; the entire contents of which are incorporated herein by reference.

### FIELD

Embodiments relate to a semiconductor device.

### BACKGROUND

Proposed is a semiconductor device such as a reverse-conducting insulated gate bipolar transistor (IGBT) obtained by integrating an IGBT and a diode into one chip. In the semiconductor device, it is desired to reduce power loss.

### BRIEF DESCRIPTION OF THE DRAWINGS

FIG. 1 is a schematic perspective view illustrating a semiconductor device according to an embodiment;

FIG. 2 is a schematic cross-sectional view illustrating the semiconductor device according to the embodiment;

FIG. 3 is a schematic cross-sectional view illustrating the semiconductor device according to the embodiment;

FIG. 4 is a schematic perspective view illustrating the semiconductor device according to the embodiment;

FIG. 5 is a schematic cross-sectional view illustrating the semiconductor device according to the embodiment;

FIG. 6 is a schematic plan view illustrating the semiconductor device according to the embodiment;

FIGS. 7A to 7C are schematic views illustrating an operation of the semiconductor device according to the embodiment;

FIG. 8 is a schematic perspective view illustrating a semiconductor device according to the embodiment;

FIG. 9 is a schematic cross-sectional view illustrating the semiconductor device according to the embodiment;

FIG. 10 is a schematic cross-sectional view illustrating the semiconductor device according to the embodiment;

FIG. 11 is a schematic perspective view illustrating a semiconductor device according to the embodiment;

FIG. 12 is a schematic perspective view illustrating a semiconductor device according to the embodiment;

FIG. 13 is a schematic cross-sectional view illustrating the semiconductor device according to the embodiment;

FIG. 14 is a schematic cross-sectional view illustrating the semiconductor device according to the embodiment;

FIG. 15 is a schematic cross-sectional view illustrating the semiconductor device according to the embodiment; and

FIG. 16 is a schematic circuit diagram illustrating a circuit using the semiconductor devices according to the embodiment.

### DETAILED DESCRIPTION

A semiconductor device according to one embodiment, includes a first electrode, a second electrode, a first interconnect, a semiconductor layer, a first control electrode, and a second control electrode. At least a portion of the second electrode is disposed in an element region. A direction from the first electrode toward the second electrode is along a first direction. The first interconnect is disposed in a first interconnect region. A direction from the element region toward the first interconnect region is along a second direction intersecting the first direction. The semiconductor layer is provided between the first electrode and the second electrode and between the first electrode and the first interconnect. The semiconductor layer includes a first semiconductor region, a second semiconductor region, a third semiconductor region, a fourth semiconductor region, a fifth semiconductor region, a sixth semiconductor region, and a seventh semiconductor. The first semiconductor region is electrically connected to the second electrode. The first semiconductor region is of a first conductivity-type. A direction from the first electrode toward the first semiconductor region is along the first direction. The first semiconductor region includes a first semiconductor portion disposed in the first interconnect region and a second semiconductor portion disposed in the element region. The second semiconductor region is provided between the first electrode and the first semiconductor region. The second semiconductor region is of a second conductivity-type. The third semiconductor region is provided between the first electrode and the second semiconductor region. The third semiconductor region is of the first conductivity-type. The fourth semiconductor region is provided between the first electrode and the second semiconductor region. The fourth semiconductor region is of the second conductivity-type. An impurity concentration of the second conductivity-type in the fourth semiconductor region is higher than an impurity concentration of the second conductivity-type in the second semiconductor region. The fifth semiconductor region is disposed in the first interconnect region. The fifth semiconductor region is electrically connected to the second electrode. The fifth semiconductor region is of the first conductivity-type. At least a portion of the first semiconductor portion is between the second semiconductor region and the fifth semiconductor region. An impurity concentration of the first conductivity-type in the fifth semiconductor region is higher than an impurity concentration of the first conductivity-type in the first semiconductor region. The sixth semiconductor region is disposed in the first interconnect region. The sixth semiconductor region is electrically connected to the second electrode. The sixth semiconductor region is of the second conductivity-type. At least a portion of the first semiconductor portion is between the second semiconductor region and the sixth semiconductor region. The seventh semiconductor region is disposed in the element region. The seventh semiconductor region is electrically connected to the second electrode. The seventh semiconductor region is of the second conductivity-type. A portion of the second semiconductor portion is between the second semiconductor region and the seventh semiconductor region. The first control electrode faces the first semiconductor region and the second semiconductor region via a first insulating portion. The first control electrode is arranged with the first semiconductor region and the second semiconductor region in a direction intersecting the first direction. The first control electrode includes a first interconnect region portion disposed in the first interconnect region. The first interconnect region portion is electrically connected to the first interconnect. The second control electrode faces the first semiconductor region, the second semiconductor region, and the seventh semiconductor region via a second insulating portion. The second control electrode is arranged with the first semiconductor region, the second semiconductor region, and the seventh semiconductor region in a direction intersecting the first direction. The second control electrode is insulated from the first interconnect.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

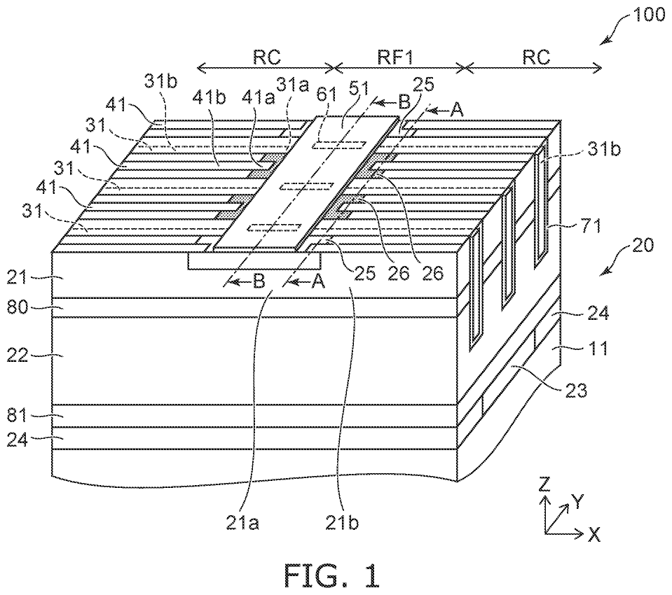

FIG. 1 is a schematic perspective view illustrating a semiconductor device according to an embodiment.

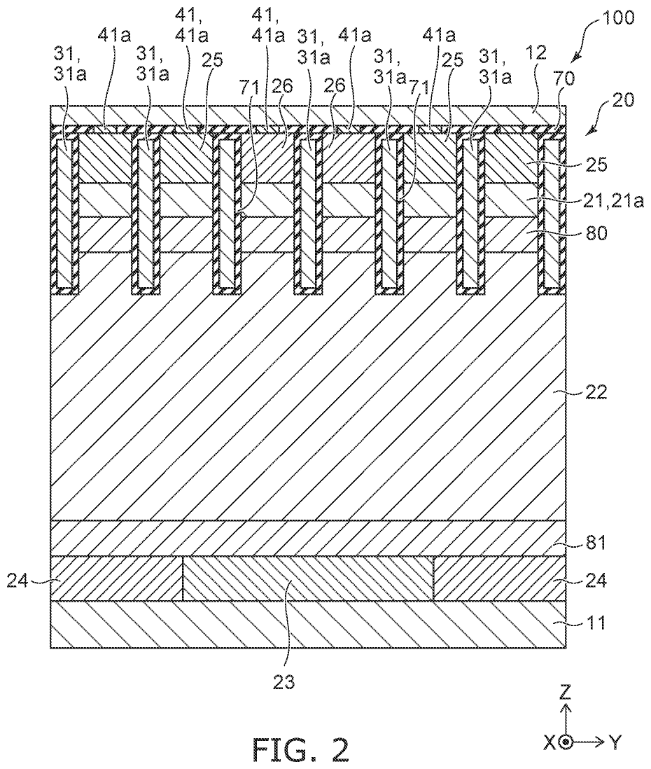

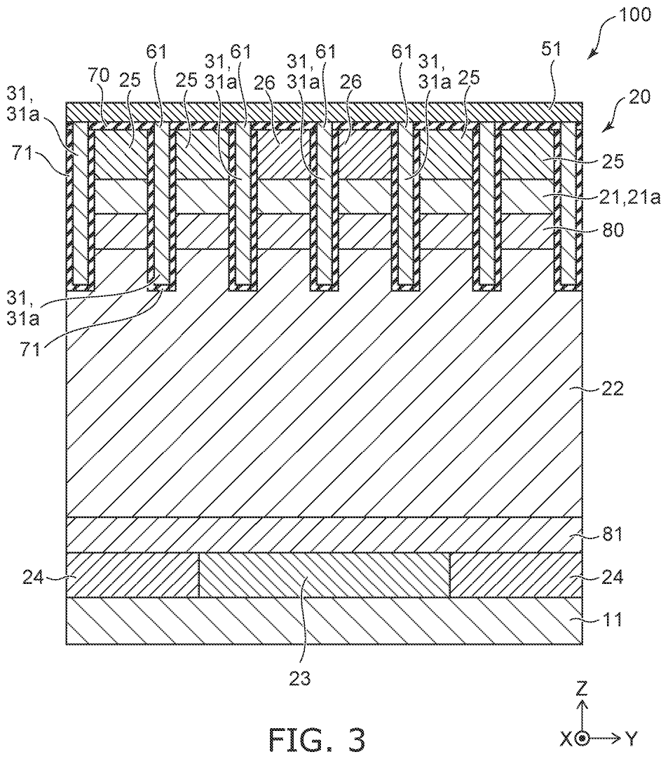

FIGS. 2 and 3 are schematic cross-sectional views illustrating the semiconductor device according to the embodiment.

FIG. 2 corresponds to a cross section taken along a line A-A shown in FIG. 1. FIG. 3 corresponds to a cross section taken along a line B-B shown in FIG. 1.

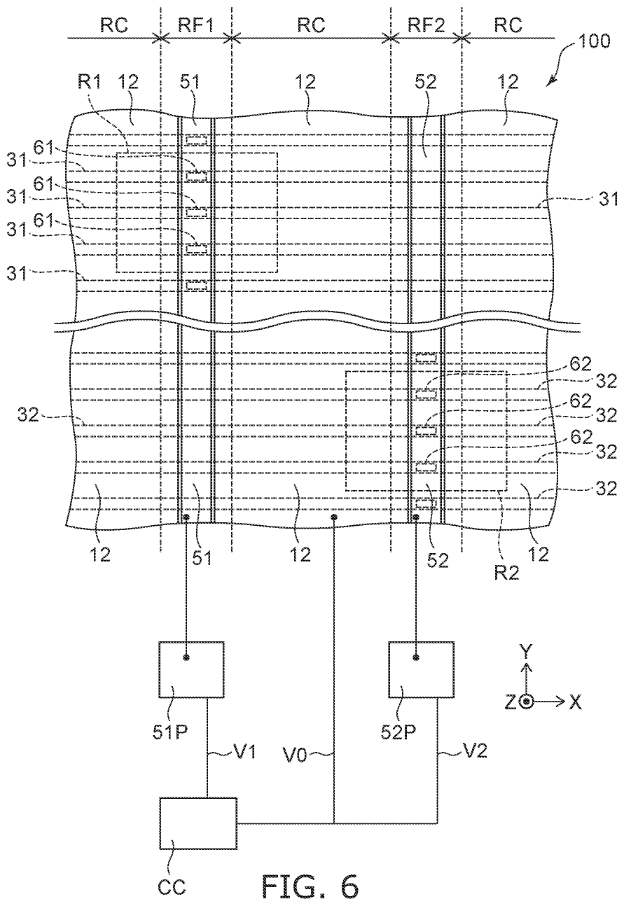

FIG. 1 corresponds to a perspective view of a portion (for example, a region R1 in a plan view shown in FIG. 6 to be described below) of a semiconductor device 100 according to the embodiment. The semiconductor device 100 is, for example, a reverse-conducting (RC)-IGBT. As shown in FIG. 1, the semiconductor device 100 includes a first electrode 11, a first interconnect 51, a semiconductor layer 20, and a first control electrode 31. As shown in FIG. 2, the semiconductor device 100 further includes a second electrode 12. In FIG. 1, the second electrode 12 is not shown.

In the description of the embodiment, a direction from the first electrode 11 toward the second electrode 12 is taken as a Z-axis direction. The Z-axis direction is along a first direction. One direction perpendicular to the Z-axis direction is taken as an X-axis direction (for example, a second direction). A direction perpendicular to the Z-axis direction and perpendicular to the X-axis direction is taken as a Y-axis direction (for example, a third direction). In the following example, a first conductivity-type is a p-type, and a second conductivity-type is an n-type. Alternatively, in the embodiment, the first conductivity-type may be the n-type; and the second conductivity-type may be the p-type.

As shown in FIG. 1, in the semiconductor device 100, element regions RC and a first interconnect region RF1 are set in an X-Y plane. The element regions RC are aligned with the first interconnect region RF1 in the second direction (for example, the X-axis direction). In other words, a direction from the element region RC toward the first interconnect region RF1 is along the second direction (for example, the X-axis direction) intersecting the first direction (for example, the Z-axis direction). The element region RC is, for example, a region where a transistor is formed.

The first interconnect region RF1 is, for example, a region where the first interconnect 51 is disposed and the first interconnect 51 is connected to the first control electrode 31. In the first interconnect region RF1, a semiconductor region to be the source of the transistor may not be formed. The first interconnect region RF1 and the first interconnect 51 extend in, for example, the Y-axis direction. The first interconnect 51 is insulated from the semiconductor layer 20 by an insulating portion 70 (see FIG. 3 and the like). The first interconnect region RF1 corresponds to a gate finger portion. The gate finger portion is a region where a gate electrode is connected to a gate interconnect.

At least a portion of the second electrode 12 is provided in the element region RC. The second electrode 12 is aligned with the first interconnect 51 in a direction (for example, the X-axis direction) in the X-Y plane. For example, the second electrode 12 extends in the X-Y plane in a manner of covering substantially the entire element region RC.

The semiconductor layer 20 is provided between the first electrode 11 and the second electrode 12 and between the first electrode 11 and the first interconnect 51. The semiconductor layer 20 includes a first semiconductor region 21, a second semiconductor region 22, a third semiconductor region 23, a fourth semiconductor region 24, a fifth semiconductor region 25, and a sixth semiconductor region 26.

The first semiconductor region 21 is electrically connected to the second electrode 12 via a first contact portion 41. A direction from the first electrode 11 toward the first semiconductor region 21 is along the first direction (for example, the Z-axis direction). The first semiconductor region 21 includes a first semiconductor portion 21a disposed in the first interconnect region RF1. That is, a portion (at least a portion of the first semiconductor portion 21a) of the first semiconductor region 21 is between the first interconnect 51 and the first electrode 11. Furthermore, the first semiconductor region 21 includes a second semiconductor portion 21b disposed in the element region RC. That is, another portion (at least a portion of the second semiconductor portion 21b) of the first semiconductor region 21 is between the second electrode 12 and the first electrode 11. The first semiconductor region 21 is of a first conductivity-type (for example, the p-type).

The second semiconductor region 22 is between the first electrode 11 and the first semiconductor region 21. The second semiconductor region 22 is located in the first interconnect region RF1 and the element region RC. The second semiconductor region 22 is of a second conductivity-type (for example, the n-type).

The third semiconductor region 23 is between the first electrode 11 and the second semiconductor region 22. The third semiconductor region 23 is located in the first interconnect region RF1 and the element region RC. The third semiconductor region 23 is of the first conductivity-type. For example, the third semiconductor region 23 is in contact with the first electrode 11 and is electrically connected to the first electrode 11.

The fourth semiconductor region 24 is between the first electrode 11 and the second semiconductor region 22. The fourth semiconductor region 24 is located in the first interconnect region RF1 and the element region RC. The fourth semiconductor region 24 is of the second conductivity-type. An impurity concentration of the second conductivity-type in the fourth semiconductor region 24 is higher than an impurity concentration of the second conductivity-type in the second semiconductor region 22. For example, the fourth semiconductor region 24 is in contact with the first electrode 11 and is electrically connected to the first electrode 11. The fourth semiconductor region 24 is aligned with the third semiconductor region 23 in a direction in the X-Y plane (for example, the Y-axis direction). For example, multiple third semiconductor regions 23 and multiple fourth semiconductor regions 24 are alternately arranged in the Y-axis direction.

The fifth semiconductor region 25 is disposed in the first interconnect region RF1. The fifth semiconductor region 25 is provided on the first semiconductor region 21 (at least a portion of the first semiconductor portion 21a) in the first interconnect region RF1. In other words, at least a portion of the first semiconductor portion 21a is between the fifth semiconductor region 25 and the second semiconductor region 22. For example, the fifth semiconductor region 25 is in contact with the first semiconductor region 21. The fifth semiconductor region 25 is of the first conductivity-type. An impurity concentration of the first conductivity-type in the fifth semiconductor region 25 is higher than an impurity concentration of the first conductivity-type in the first semiconductor region 21. The fifth semiconductor region 25 is electrically connected to the second electrode 12 via the first contact portion 41. For example, multiple fifth semiconductor regions 25 may be provided. The multiple fifth semiconductor regions 25 are arranged on the first semiconductor region 21 in a direction (the X-axis direction or the Y-axis direction) in the X-Y plane.

The sixth semiconductor region 26 is disposed in the first interconnect region RF1. The sixth semiconductor region 26 is provided on the first semiconductor region 21 (at least a portion of the first semiconductor portion 21a) in the first interconnect region RF1. In other words, at least a portion of the first semiconductor portion 21a is between the sixth semiconductor region 26 and the second semiconductor region 22. For example, the sixth semiconductor region 26 is in contact with the first semiconductor region 21. The sixth semiconductor region 26 is of the second conductivity-type. For example, an impurity concentration of the second conductivity-type in the sixth semiconductor region 26 is higher than an impurity concentration of the second conductivity-type in the second semiconductor region 22. The sixth semiconductor region 26 is electrically connected to the second electrode 12 via the first contact portion 41. For example, multiple sixth semiconductor regions 26 may be provided. The multiple sixth semiconductor regions 26 are arranged on the first semiconductor region 21 in a direction (the X-axis direction or the Y-axis direction) in the X-Y plane.

For example, in examples shown in FIGS. 1 to 3, one or more sixth semiconductor regions 26 are provided between two fifth semiconductor regions 25 arranged in the Y-axis direction. One or more fifth semiconductor regions 25 may be provided between two sixth semiconductor regions 26 arranged in the Y-axis direction. The fifth semiconductor regions 25 and the sixth semiconductor regions 26 may be alternately arranged in the Y-axis direction. The fifth semiconductor regions 25 may be in contact with the sixth semiconductor regions 26.

The semiconductor layer 20 may further be provided with a semiconductor region 80 and a semiconductor region 81. The semiconductor region 80 is between the first semiconductor region 21 and the second semiconductor region 22. The semiconductor region 80 is of the second conductivity-type. An impurity concentration of the second conductivity-type in the semiconductor region 80 is higher than an impurity concentration of the second conductivity-type in the second semiconductor region 22. The semiconductor region 81 is between the second semiconductor region 22 and the fourth semiconductor region 24 and between the second semiconductor region 22 and the third semiconductor region 23. The semiconductor region 81 is of the second conductivity-type. An impurity concentration of the second conductivity-type in the semiconductor region 81 is higher than the impurity concentration of the second conductivity-type in the second semiconductor region 22 and lower than the impurity concentration of the second conductivity-type in the fourth semiconductor region 24.

The first control electrode 31 is aligned with the first semiconductor region 21 and the second semiconductor region 22 in a direction (for example, the Y-axis direction) intersecting the first direction. The first control electrode 31 faces the first semiconductor region 21 and the second semiconductor region 22 via a first insulating portion 71. The first control electrode 31 is insulated from the semiconductor layer 20 by the first insulating portion 71. For example, the semiconductor layer 20 is provided with a trench that reaches the second semiconductor region 22 from the first semiconductor region 21. The first insulating portion 71 is provided in an inner wall of the trench. The first control electrode 31 is provided inside the first insulating portion 71 in the trench.

For example, the first control electrode 31 extends in the X-axis direction. The first control electrode 31 is provided in the first interconnect region RF1 and the element region RC. More specifically, as shown in FIG. 1, the first control electrode 31 includes a portion (a first interconnect region portion 31a) disposed in the first interconnect region RF1 and a portion (a first element region portion 31b) disposed in the element region RC.

For example, as shown in FIG. 1, in the element region RC, the first insulating portion 71 is located between the first element region portion 31b and the semiconductor layer 20 (each of the first semiconductor region 21 and the second semiconductor region 22). In the element region RC, the first insulating portion 71 is in contact with the first element region portion 31b, the first semiconductor region 21 (the second semiconductor portion 21b), and the second semiconductor region 22.

For example, as shown in FIG. 2, in the first interconnect region RF1, the first insulating portion 71 is located between the first interconnect region portions 31a and the semiconductor layer 20 (each of the first semiconductor region 21, the second semiconductor region 22, the fifth semiconductor region 25, and the sixth semiconductor region 26). The first insulating portion 71 is in contact with each of the first interconnect region portions 31a, the first semiconductor region 21 (the first semiconductor portion 21a), the second semiconductor region 22, the fifth semiconductor region 25, and the sixth semiconductor region 26.

For example, as shown in FIG. 3, the first interconnect 51 is located on a portion of the first interconnect region portions 31a. In other words, the first interconnect region portions 31a are between the first interconnect 51 and the second semiconductor region 22. The first interconnect region portions 31a are electrically connected to the first interconnect 51 in the first interconnect region RF1. Specifically, conductive portions 61 (contact) are provided that electrically connect the first interconnect region portions 31a and the first interconnect 51. The conductive portions 61 are provided between the first interconnect region portions 31a and the first interconnect 51 and are in contact with the first interconnect region portions 31a and the first interconnect 51.

Multiple first control electrodes 31 may be provided. For example, the multiple first control electrodes 31 are arranged in the Y-axis direction, and each of the first control electrodes 31 extends in the X-axis direction.

The first contact portion 41 is a conductive portion provided on the semiconductor layer 20 and electrically connects the semiconductor layer 20 and the second electrode 12. The first contact portion 41 may be a conductive portion continuous with the second electrode 12 or may be a portion of the second electrode 12. For example, as shown in FIG. 1, the first contact portion 41 extends in the X-axis direction. The first contact portion 41 includes a portion (a first contact region 41a) disposed in the first interconnect region RF1 and a portion (a second contact region 41b) disposed in the element region RC.

For example, as shown in FIG. 2, the first contact regions 41a are provided between the second electrode 12 and at least one of the fifth semiconductor region 25 and the sixth semiconductor region 26. The first contact regions 41a are in contact with at least one of the fifth semiconductor region 25 and the sixth semiconductor region 26 and are in contact with the second electrode 12. Accordingly, the first contact regions 41a electrically connect the second electrode 12 and at least one of the fifth semiconductor region 25 and the sixth semiconductor region 26 in the first interconnect region RF1.

The second contact region 41b disposed in the element region RC is provided between the first semiconductor region 21 and the second electrode 12 and is in contact with each of the first semiconductor region 21 and the second electrode 12. Accordingly, the second contact region 41b electrically connects the first semiconductor region 21 and the second electrode 12 in the element region RC.

Multiple first contact portions 41 may be provided. For example, the multiple first contact portions 41 are arranged in the Y-axis direction, and each of the first contact portions 41 extends in the X-axis direction. For example, the first contact portions 41 and the first control electrodes 31 are alternately arranged in the Y-axis direction.

In the example, one of the multiple first contact regions 41a is in contact with the fifth semiconductor region 25 and is separated from the sixth semiconductor region 26. Another one of the multiple first contact regions 41a is in contact with the sixth semiconductor region 26 and is separated from the fifth semiconductor region 25.

For example, as shown in FIG. 2, the insulating portion 70 is provided between the semiconductor layer 20 and the second electrode 12. For example, as shown in FIG. 3, the insulating portion 70 is provided between the semiconductor layer 20 and the first interconnect 51. The second electrode 12 is insulated from the first control electrode 31 and the first interconnect 51.

Accordingly, in the embodiment, the sixth semiconductor region 26 of the second conductivity-type is provided in the first interconnect region RF1. As described below, for example, carriers (electrons) are extracted from the semiconductor layer 20 via the sixth semiconductor region 26. Accordingly, for example, a carrier concentration in the semiconductor layer 20 is controlled, and it is possible to reduce power loss such as turn on loss or recovery loss. In this case, by further providing the fifth semiconductor region 25, as described below, for example, latch-up of a parasitic thyristor at the time of recovery can be prevented.

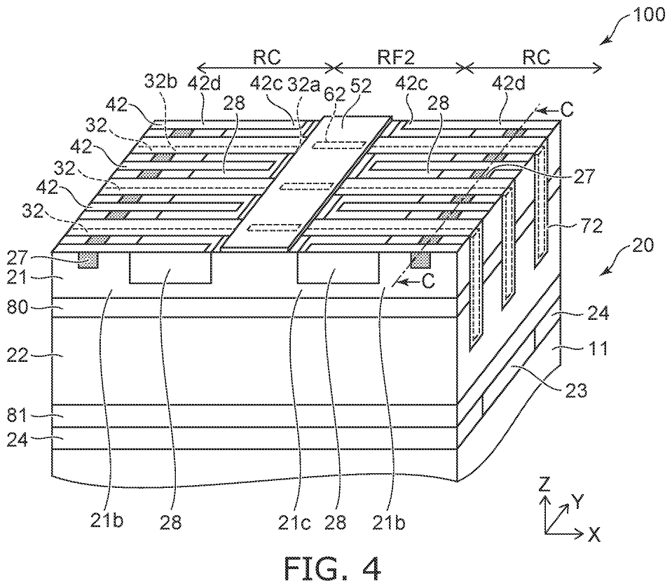

FIG. 4 is a schematic perspective view illustrating the semiconductor device according to the embodiment.

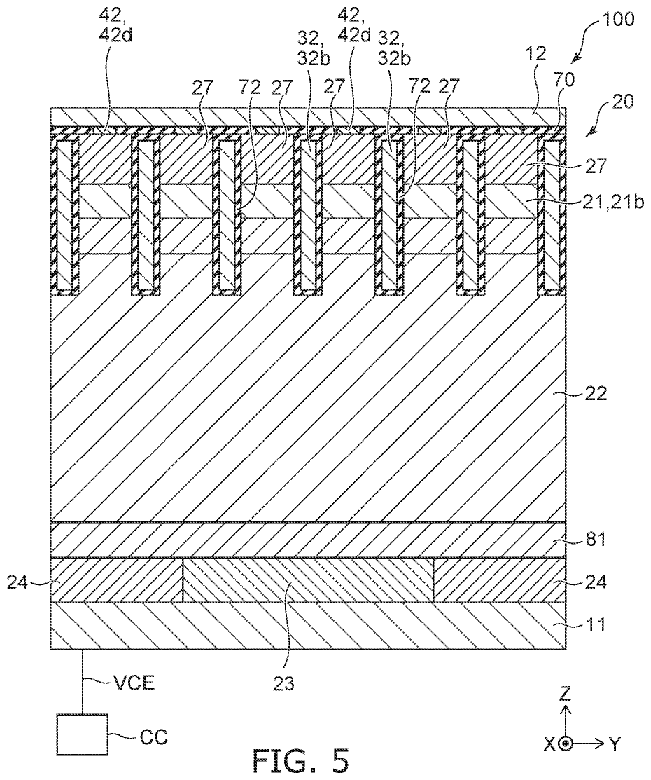

FIG. 5 is a schematic cross-sectional view illustrating the semiconductor device according to the embodiment.

FIG. 4 corresponds to a perspective view of a portion (for example, a region R2 in a plan view shown in FIG. 6 to be described below) of the semiconductor device 100. FIG. 5 corresponds to a cross section taken along a line C-C shown in FIG. 4. In FIG. 4, the second electrode 12 is not shown.

The semiconductor device 100 further includes a second interconnect 52 and a second control electrode 32. As shown in FIG. 4, the semiconductor device 100 is further formed with a second interconnect region RF2. The element region RC is aligned with the second interconnect region RF2 in the X-axis direction. In other words, a direction from the element region RC toward the second interconnect region RF2 is along the direction (for example, the X-axis direction) intersecting the first direction (for example, the Z-axis direction).

The second interconnect region RF2 is a region where, for example, the second interconnect 52 is disposed and the second interconnect 52 is connected to the second control electrode 32. A semiconductor region to be the source of the transistor may not be formed in the second interconnect region RF2. The second interconnect region RF2 and the second interconnect 52 extend in, for example, the Y-axis direction. For example, the second interconnect 52 is aligned with the second electrode 12 in the X-axis direction. The second interconnect 52 is insulated from the semiconductor layer 20 by, for example, an insulating portion.

The semiconductor layer 20 is also disposed in the second interconnect region RF2. That is, a portion of the semiconductor layer 20 is provided between the first electrode 11 and the second interconnect 52. Similarly to the first interconnect region RF1 and the element region RC, in the second interconnect region RF2, the first electrode 11, the first semiconductor region 21, the second semiconductor region 22, the third semiconductor region 23, the fourth semiconductor region 24, and the semiconductor regions 80, 81 are also provided. As shown in FIG. 4, the semiconductor layer 20 further has a seventh semiconductor region 27 and an eighth semiconductor region 28.

The first semiconductor region 21 further includes a third semiconductor portion 21c disposed in the second interconnect region RF2. That is, a portion (at least a portion of the third semiconductor portion 21c) of the first semiconductor region 21 is between the second interconnect 52 and the first electrode 11.

The seventh semiconductor region 27 is provided in the element region RC. The seventh semiconductor region 27 is provided on the first semiconductor region 21 (a portion of the second semiconductor portion 21b) in the element region RC. In other words, the portion of the second semiconductor portion 21b is between the second semiconductor region 22 and the seventh semiconductor region 27. The seventh semiconductor region 27 is of the second conductivity-type. An impurity concentration of the second conductivity-type in the seventh semiconductor region 27 is, for example, higher than the impurity concentration of the second conductivity-type in the second semiconductor region 22. The seventh semiconductor region 27 is electrically connected to the second electrode 12 via a second contact portion 42. For example, multiple seventh semiconductor regions 27 may be provided. The multiple seventh semiconductor regions 27 are arranged on the first semiconductor region 21 in a direction (the X-axis direction or the Y-axis direction) in the X-Y plane. For example, in the examples shown in FIGS. 4 and 5, one second control electrode 32 (and a second insulating portion 72) is provided between two seventh semiconductor regions 27. That is, the seventh semiconductor regions 27 and the second control electrodes 32 are alternately arranged in the Y-axis direction.

The eighth semiconductor region 28 is arranged in the second interconnect region RF2 and the element region RC. The eighth semiconductor region 28 is provided on the first semiconductor region 21 (a portion of the second semiconductor portion 21b and a portion of the third semiconductor portion 21c) along a boundary between the second interconnect region RF2 and the element region RC. In other words, at least a portion of the third semiconductor portion 21c is between the eighth semiconductor region 28 and the second semiconductor region 22. The eighth semiconductor region 28 is of the first conductivity-type. An impurity concentration of the first conductivity-type in the eighth semiconductor region 28 is, for example, higher than the impurity concentration of the first conductivity-type in the first semiconductor region 21. The eighth semiconductor region 28 is electrically connected to the second electrode 12 via the second contact portion 42.

The second control electrode 32 is aligned with the first semiconductor region 21, the second semiconductor region 22, and the seventh semiconductor region 27 in a direction (for example, the Y-axis direction) intersecting the first direction. The second control electrode 32 faces the first semiconductor region 21, the second semiconductor region 22, and the seventh semiconductor region 27 via the second insulating portion 72. The second control electrode 32 is insulated from the semiconductor layer 20 by the second insulating portion 72. For example, the semiconductor layer 20 is provided with a trench that reaches the second semiconductor region 22 from the first semiconductor region 21. The second insulating portion 72 is provided in an inner wall of the trench. The second control electrode 32 is provided inside the second insulating portion 72 in the trench.

For example, the second control electrode 32 extends in the X-axis direction. The second control electrode 32 is provided in the second interconnect region RF2 and the element region RC. More specifically, as shown in FIG. 4, the second control electrode 32 includes a portion (a second interconnect region portion 32a) disposed in the second interconnect region RF2 and a portion (a second element region portion 32b) disposed in the element region RC.

For example, in the second interconnect region RF2, the second insulating portion 72 is located between the second interconnect region portion 32a and the semiconductor layer 20 (each of the first semiconductor region 21 and the second semiconductor region 22). In the second interconnect region RF2, the second insulating portion 72 is in contact with the second interconnect region portion 32a, the first semiconductor region 21, and the second semiconductor region 22.

For example, as shown in FIG. 5, in the element region RC, the second insulating portion 72 is located between the second element region portion 32b and the semiconductor layer 20 (each of the first semiconductor region 21, the second semiconductor region 22, and the seventh semiconductor region 27). The second insulating portion 72 is in contact with each of the second element region portion 32b, the first semiconductor region 21 (the second semiconductor portion 21b), the second semiconductor region 22, and the seventh semiconductor region 27.

For example, as shown in FIG. 4, the second interconnect 52 is located on a portion of the second interconnect region portion 32a. In other words, the second interconnect region portion 32a is between the second interconnect 52 and the second semiconductor region 22. The second interconnect region portion 32a is electrically connected to the second interconnect 52 in the second interconnect region RF2. Specifically, a conductive portion 62 (contact) is provided that electrically connects the second interconnect region portion 32a and the second interconnect 52. The conductive portion 62 is provided between the second interconnect region portion 32a and the second interconnect 52 and is in contact with the second interconnect region portion 32a and the second interconnect 52.

Multiple second control electrodes 32 may be provided. For example, the multiple second control electrodes 32 are arranged in the Y-axis direction, and each of the second control electrodes 32 extends in the X-axis direction.

The second contact portion 42 is a conductive portion provided on the semiconductor layer 20 and electrically connects the semiconductor layer 20 and the second electrode 12. The second contact portion 42 may be a conductive portion continuous with the second electrode 12 or may be a portion of the second electrode 12. For example, as shown in FIG. 4, the second contact portion 42 extends in the X-axis direction. The second contact portion 42 includes a portion (a third contact region 42c) disposed in the second interconnect region RF2 and a portion (a fourth contact region 42d) disposed in the element region RC.

The third contact region 42c disposed in the second interconnect region is provided between the second electrode 12 and the eighth semiconductor region 28. The third contact region 42c is in contact with the eighth semiconductor region 28 and is in contact with the second electrode 12. Accordingly, the third contact region 42c electrically connects the second electrode 12 and the eighth semiconductor region 28 in the second interconnect region RF2.

The fourth contact region 42d arranged in the element region RC is provided between the second electrode 12 and each of the first semiconductor region 21 and the seventh semiconductor region 27, and is in contact with each of the second electrode 12, the first semiconductor region 21, and the seventh semiconductor region 27. Accordingly, in the element region RC, the fourth contact regions 42d electrically connect the second electrode 12 and the first semiconductor region 21 and electrically connect the second electrode 12 and the seventh semiconductor region 27.

Multiple second contact portions 42 may be provided. For example, the multiple second contact portions 42 are arranged in the Y-axis direction, and each of the second contact portions 42 extends in the X-axis direction. For example, the second contact portions 42 and the second control electrodes 32 are alternately arranged in the Y-axis direction.

For example, as shown in FIG. 5, the insulating portion 70 is provided between the semiconductor layer 20 and the second electrode 12. The insulating portion 70 may also be provided between the semiconductor layer 20 and the second interconnect 52. The second electrode 12 is insulated from the second control electrode 32 and the second interconnect 52.

FIG. 6 is a schematic plan view illustrating the semiconductor device according to the embodiment.

In the example shown in FIG. 6, the multiple first control electrodes 31 are aligned with the multiple second control electrodes 32 in the Y-axis direction. The first interconnect 51 (the first interconnect region RF1) is aligned with the second interconnect 52 (the second interconnect region RF2) in the X-axis direction. The first interconnect 51 is electrically connected to each of the multiple first control electrodes 31. The second interconnect 52 is electrically connected to each of the multiple second control electrodes 32.

FIG. 6 is an example, and arrangement of the first control electrodes 31, the second control electrodes 32, the first interconnect 51, the second interconnect 52, and the like is not limited thereto. For example, one or more second control electrodes 32 may be disposed between two first control electrodes 31, or one or more first control electrodes 31 may be disposed between two second control electrodes 32. The first interconnect 51 and the second interconnect 52 may not be aligned in the X-axis direction or may be aligned in the Y-axis direction.

As in the example shown in FIG. 6, the first control electrodes 31 may extend to the second interconnect region RF2. That is, the second interconnect 52 may be located above the first control electrode 31. However, the first control electrode 31 is insulated from the second interconnect 52. For example, an insulating film (not shown) is disposed between the first control electrode 31 and the second interconnect 52, and a contact connecting the first control electrode 31 and the second interconnect 52 is not provided.

Similarly, the second control electrodes 32 may extend to the first interconnect region RF1. That is, the first interconnect 51 may be located above the second control electrode 32. However, the second control electrode 32 is insulated from the first interconnect 51. For example, an insulating film (not shown) is disposed between the second control electrode 32 and the first interconnect 51, and a contact connecting the second control electrode 32 and the first interconnect 51 is not provided.

Accordingly, the first control electrode 31 is electrically insulated from the second control electrode 32. As shown in FIG. 6, the semiconductor device 100 further includes a first electrode pad 51P and a second electrode pad 52P. The first electrode pad 51P is electrically connected to the first control electrode 31 via the first interconnect 51. The first electrode pad 51P is insulated from the second control electrode 32. The second electrode pad 52P is electrically connected to the second control electrode 32 via the second interconnect 52. The second electrode pad 52P is insulated from the first control electrode 31. By applying a voltage from the outside to each of the first electrode pad 51P and the second electrode pad 52P, a potential of the first control electrode 31 and a potential of the second control electrode 32 can be controlled separately.

The element region RC corresponds to a region between the first interconnect regions RF1 serving as gate finger portions, a region between the second interconnect regions RF2, and a region between the first interconnect regions RF1 and the second interconnect regions RF2.

An example of a material of each element of the semiconductor device 100 will be described.

Each of the semiconductor regions (the first semiconductor region 21 to the eighth semiconductor region 28, and the like) of the semiconductor layer 20 contains silicon, silicon carbide, gallium nitride, or gallium arsenide as a semiconductor material. When silicon is used as the semiconductor material, arsenic, phosphorus, or antimony can be used as the n-type impurity. Boron can be used as the p-type impurity.

The first control electrode 31 and the second control electrode 32 (and a conductive member 33 to be described below) contain a conductive material such as polysilicon.

The insulating portion 70, the first insulating portion 71, and the second insulating portion 72 (and a third insulating portion 73 to be described below) contain an insulating material such as silicon oxide.

The first interconnect 51, the second interconnect 52, the first electrode 11, the second electrode 12, the first electrode pad 51P, and the second electrode pad 52P contain a metal such as aluminum.

As described above, the semiconductor device 100 operates as an RC-IGBT.

In a state where a positive voltage is applied to the first electrode 11 (for example, a collector electrode) with respect to the second electrode 12 (for example, an emitter electrode), a voltage not less than a threshold is applied to the first control electrode 31 and the second control electrode 32 (for example, gate electrodes). Accordingly, an inversion layer (an n-type inversion layer) is formed in the first semiconductor region 21 (for example, a p-type base region), and the IGBT operation is started in the element region RC. For example, a channel (the inversion layer) is formed in a region of the first semiconductor region 21 facing the second control electrode 32. For example, electrons flow from the second electrode 12 to the second semiconductor region 22 (for example, a drift region) through the seventh semiconductor region 27 (for example, a source region) and the channel. For example, holes flow from the first electrode 11 to the second semiconductor region 22 through the third semiconductor region 23 (for example, a collector region). Thereafter, when the voltage applied to the first control electrode 31 and the second control electrode 32 is lower than the threshold, the inversion layer in the first semiconductor region 21 disappears, and the IGBT operation ends.

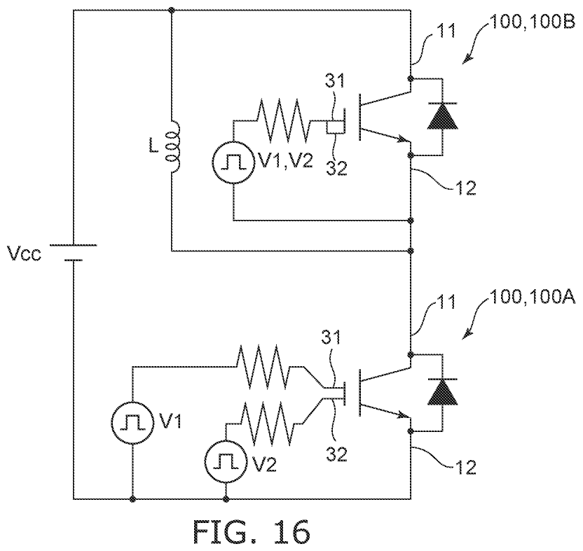

Multiple semiconductor devices 100 constitute, for example, a circuit (see, for example, FIG. 16). When the IGBT operation ends in one semiconductor device 100 in the circuit, an induced electromotive force is applied to the second electrode 12 of another semiconductor device 100 due to an inductance component of the circuit. When the induced electromotive force is applied to the second electrode 12, the other semiconductor device 100 operates as a diode. During diode operation, for example, holes flow from the second electrode 12 to the second semiconductor region 22 through the first semiconductor region 21, the fifth semiconductor region 25, and the eighth semiconductor region 28. For example, the electrons flow from the first electrode 11 to the second semiconductor region 22 through the fourth semiconductor region 24 (for example, a cathode region).

When the diode operation of the semiconductor device 100 ends, the holes accumulated in the second semiconductor region 22 are discharged to the second electrode 12 through the first semiconductor region 21, the fifth semiconductor region 25, and the eighth semiconductor region 28. The electrons accumulated in the second semiconductor region 22 are discharged to the first electrode 11 through the fourth semiconductor region 24.

As shown in FIG. 6, the semiconductor device 100 may be provided with a control unit CC. The control unit CC includes a control circuit such as a CPU. The control unit CC is electrically connected to the first control electrode 31 via the first electrode pad 51P and the first interconnect 51. The control unit CC is electrically connected to the second control electrode 32 via the second electrode pad 52P and the second interconnect 52. The control unit CC is electrically connected to the second electrode 12. The control unit CC is also electrically connected to the first electrode 11 (see FIG. 5).

The control unit CC sets the second electrode 12 to a reference potential V0. The reference potential V0 is, for example, a ground potential. For example, the control unit CC applies a voltage VCE to the first electrode 11. The control unit CC applies a voltage V1 to the first control electrode 31. The control unit CC applies a voltage V2 to the second control electrode 32.

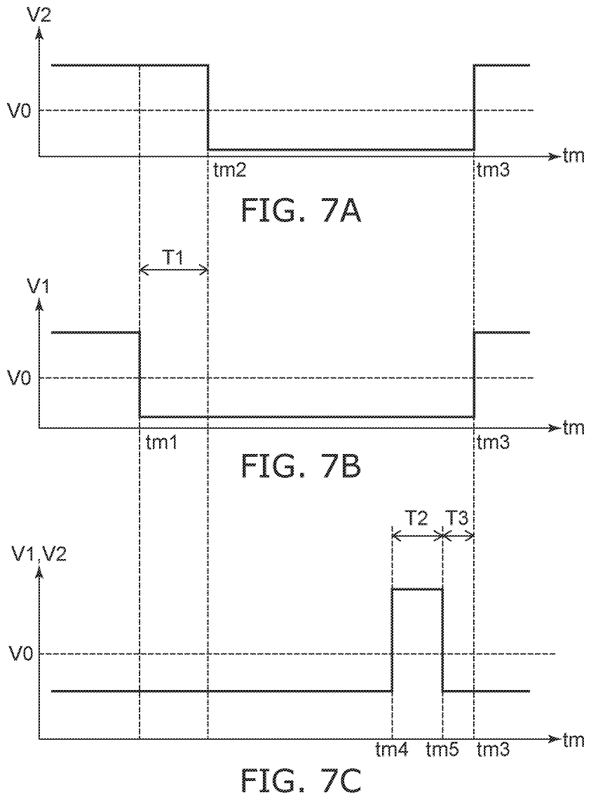

FIGS. 7A to 7C are schematic views illustrating an operation of the semiconductor device according to the embodiment.

The horizontal axis shown in FIGS. 7A to 7C is time tm. FIGS. 7A and 7B illustrate the voltage V1 and the voltage V2 in the IGBT operation of one semiconductor device 100 (for example, a first semiconductor device 100A shown in FIG. 16). For example, before a time tm1, the voltage V1 and the voltage V2 are positive (an on state). At this time, for example, n-type inversion layers are formed at an interface between the first semiconductor region 21 and the first insulating portion 71 and an interface between the first semiconductor region 21 and the second insulating portion 72. For example, the electrons flow from the second electrode 12 to the second semiconductor region 22 via the n-type inversion layer formed at the interface between the first semiconductor region 21 and the second insulating portion 72.

For example, at the time tm1, the voltage V1 changes from positive to negative (an off state). Accordingly, for example, at the interface between the first semiconductor region 21 and the first insulating portion 71, the n-type inversion layer disappears, and a p-type accumulation layer is formed. For example, at a time tm2 after the time tm1, the voltage V2 changes from positive to negative (the off state). Accordingly, for example, at the interface between the first semiconductor region 21 and the first insulating portion 71, the n-type inversion layer disappears, and a p-type accumulation layer is formed. A potential of the first control electrode 31 or the second control electrode 32 in the off state is lower than a potential of the first control electrode 31 or the second control electrode 32 in the on state. For example, the potential of the first control electrode 31 or the second control electrode 32 in the off state is lower than a potential (the reference potential V0) of the second electrode 12.

For example, at a time tm3 after the time tm2, the voltage V1 and the voltage V2 change from negative to positive.

Accordingly, in one example of the semiconductor device 100, the first control electrode 31 is turned off before the second control electrode 32 is turned off. For example, the control unit CC turns off the first control electrode 31 before the second control electrode 32 is turned off. By such an operation, for example, it is possible to reduce a loss generated when the semiconductor device 100 is turned off.

In a period T1 between the time tm1 and the time tm2, for example, the p-type inversion layer is formed at the interface between the first insulating portion 71 and each of the second semiconductor region 22 and the semiconductor region 80, and the holes are discharged from the second semiconductor region 22 to the second electrode 12. By controlling a concentration of accumulated carriers, for example, it is possible to reduce a loss generated when the second control electrode 32 is turned off. For example, the length (a difference between the time tm1 and the time tm2) of the period T1 can be set to 10 microseconds or more and 100 microseconds or less.

FIG. 7C illustrates the voltage V1 and the voltage V2 in the diode operation. For example, FIG. 7C shows the voltage V1 and the voltage V2 in another semiconductor device 100 (for example, a second semiconductor device 100B shown in FIG. 16) constituting a circuit with the first semiconductor device 100A. The operation shown in FIGS. 7A to 7C may be repeated.

For example, in the diode operation, the voltage V1 and the voltage V2 are negative (the off state) between the times tm1, tm2 and a time tm4. When the voltage V1 and the voltage V2 are negative, for example, a p-type accumulation layer is formed at the interface between the first semiconductor region 21 and the first insulating portion 71 and the interface between the first semiconductor region 21 and the second insulating portion 72. As described above, for example, the holes flow from the second electrode 12 to the second semiconductor region 22.

At the time tm4 after the time tm2, the voltage V1 and the voltage V2 change from negative to positive (the on state). At a time tm5 after the time tm4, the voltage V1 and the voltage V2 change from positive to negative again. The time tm5 is, for example, a time immediately before the time tm3. A period T3 is provided between the time tm5 and the time tm3. Accordingly, in the diode operation in which a current flows from the second electrode 12 to the first electrode 11, the first control electrode 31 and the second control electrode 32 are turned on. By such an operation, for example, a recovery loss of the diode can be reduced.

For example, in a period T2 from the time tm4 to the time tm5, for example, at the interface between the first semiconductor region 21 and the first insulating portion 71 and the interface between the first semiconductor region 21 and the second insulating portion 72, the p-type accumulation layer disappears, and the n-type inversion layer is formed. Accordingly, for example, the electrons are drawn from the second semiconductor region 22 to the second electrode 12 via the n-type inversion layer at the interface between the first semiconductor region 21 and the second insulating portion 72. By controlling the concentration of the accumulated carriers, for example, the loss at the time of an end of the diode operation can be reduced. As an example, the length (the duration of the on state of the first control electrode 31 and the second control electrode 32) of the period T2 can be set to 10 microseconds or more and 100 microseconds or less.

As described above, the sixth semiconductor region 26 of the second conductivity-type (n-type) is provided in the first interconnect region RF1. For example, the accumulated carriers can be reduced by drawing the electrons from the second semiconductor region 22 to the second electrode 12 via the sixth semiconductor region 26. For example, the electrons are drawn in the period T2. Accordingly, for example, the recovery loss can be reduced.

On the other hand, in the second interconnect region RF2, the sixth semiconductor region 26 (the semiconductor region of the second conductivity-type) is not provided on the first semiconductor region 21. Accordingly, for example, it is possible to reduce an influence of switching the second control electrode 32 to the off state on an interruption operation of the IGBT. When the semiconductor region of the second conductivity-type is not provided in the second interconnect region RF2, the third contact region 42c is not in contact with the semiconductor region of the second conductivity-type in the second interconnect region RF2.

On the other hand, when the sixth semiconductor region 26 of the second conductivity-type is formed in the first interconnect region RF1, a reverse recovery current of the diode operation may flow excessively. For example, as shown in FIG. 2, in the first interconnect region RF1, a parasitic npn transistor is formed by the sixth semiconductor region 26 of the second conductivity-type, the first semiconductor region 21 of the first conductivity-type, and the second semiconductor region 22 of the second conductivity-type. For example, a parasitic pnp transistor is formed by the first semiconductor region 21 of the first conductivity-type, the second semiconductor region 22 of the second conductivity-type, and the third semiconductor region 23 of the first conductivity-type. For example, during recovery, when the holes flow in the first semiconductor region 21 below the sixth semiconductor region 26, a voltage drop may occur, and the parasitic npn transistor may be turned on. Accordingly, the parasitic pnp transistor may be turned on, and latch-up of a parasitic element may occur.

In contrast, in the embodiment, in the first interconnect region RF1, the fifth semiconductor region 25 of the first conductivity-type is provided in the vicinity of the sixth semiconductor region 26. Accordingly, for example, the holes are likely to be drawn from the fifth semiconductor region 25, and the parasitic npn transistor can be prevented from being turned on. Latch-up of a parasitic thyristor during recovery can be prevented. According to the embodiment, for example, the recovery loss can be reduced while preventing an operation of the parasitic thyristor.

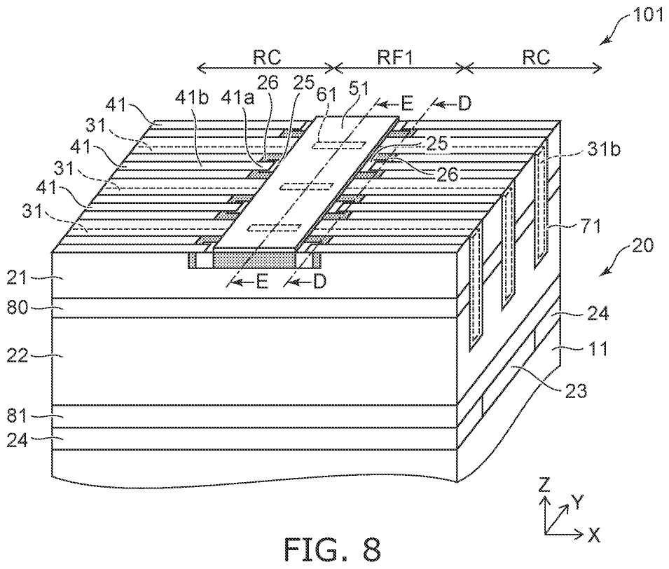

FIG. 8 is a schematic perspective view illustrating a semiconductor device according to the embodiment.

FIG. 8 illustrates the first interconnect region RF1 and the element regions RC in a semiconductor device 101 according to the embodiment. The semiconductor device 101 shown in FIG. 8 is different from the semiconductor device 100 shown in FIG. 1 and the like in arrangement of the fifth semiconductor region 25 and the sixth semiconductor region 26.

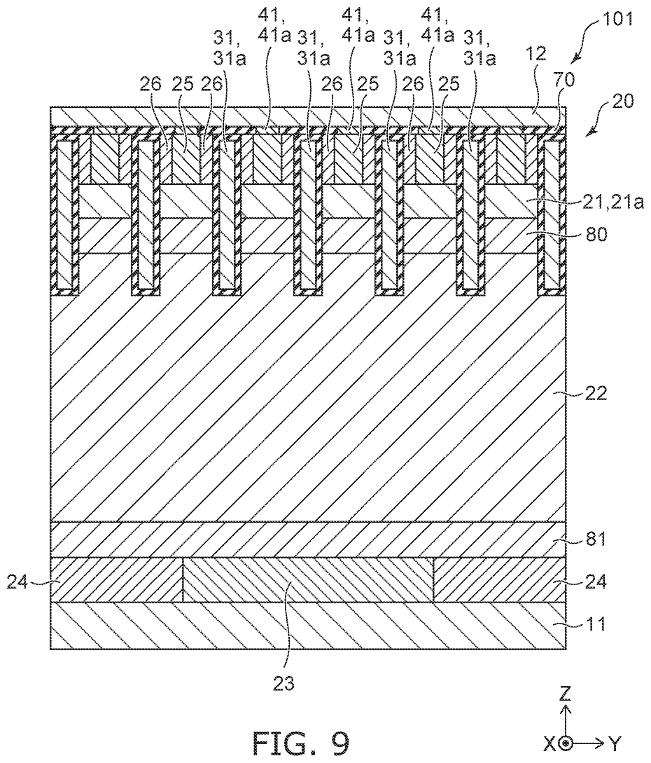

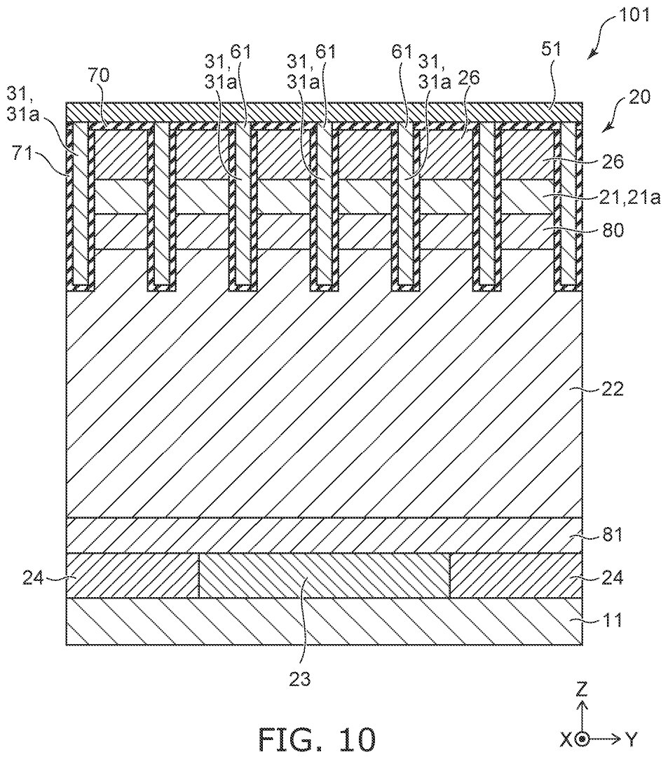

FIGS. 9 and 10 are schematic cross-sectional views illustrating the semiconductor device according to the embodiment.

FIG. 9 corresponds to a cross section taken along a line D-D shown in FIG. 8. FIG. 10 corresponds to a cross section taken along a line E-E shown in FIG. 8.

In the semiconductor device 101, one fifth semiconductor region 25 is aligned with the sixth semiconductor region 26 in the X-axis direction and the Y-axis direction. For example, one fifth semiconductor region 25 is surrounded by the sixth semiconductor region 26 in the X-Y plane. For example, as shown in FIG. 10, the sixth semiconductor region 26 may be provided below the first interconnect 51, and the fifth semiconductor region 25 may not be provided.

The first contact region 41a of each of the multiple first contact portions 41 is in contact with the fifth semiconductor region 25 and the sixth semiconductor region 26. End portions of the first contact region 41a in the X-axis direction are in contact with the fifth semiconductor region 25. In this example, for example, the loss can also be reduced while preventing the operation of the parasitic thyristor.

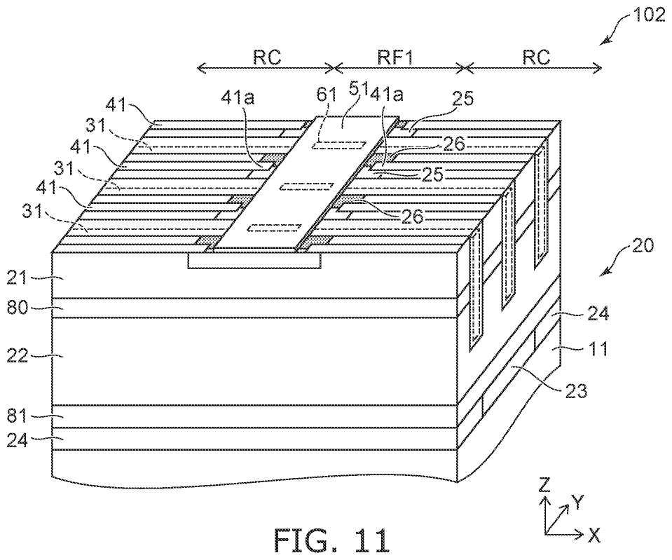

FIG. 11 is a schematic perspective view illustrating a semiconductor device according to the embodiment.

FIG. 11 illustrates the first interconnect region RF1 and the element regions RC in a semiconductor device 102 according to the embodiment. The semiconductor device 102 shown in FIG. 11 is different from the semiconductor device 100 shown in FIG. 1 and the like in arrangement of the fifth semiconductor region 25 and the sixth semiconductor region 26.

In the semiconductor device 102, the sixth semiconductor region 26 is aligned with the fifth semiconductor region 25 in a direction (for example, the Y-axis direction) intersecting the first direction and the second direction. Specifically, in this example, multiple fifth semiconductor regions 25 and multiple sixth semiconductor regions 26 are alternately arranged in the Y-axis direction. One fifth semiconductor region 25 and one sixth semiconductor region 26 are disposed between two first control electrodes 31 adjacent to each other. The fifth semiconductor regions 25 and the sixth semiconductor regions 26 extend below the first interconnect 51 in the X-axis direction.

One first contact region 41a is in contact with each of both end portions of the fifth semiconductor region 25 in the X-axis direction. One first contact region 41a is in contact with each of both end portions of the sixth semiconductor region 26 in the X-axis direction. End portions of one first contact region 41a in the X-axis direction are in contact with the fifth semiconductor region 25 and the sixth semiconductor region 26. In this example, for example, the loss can also be reduced while preventing the operation of the parasitic thyristor.

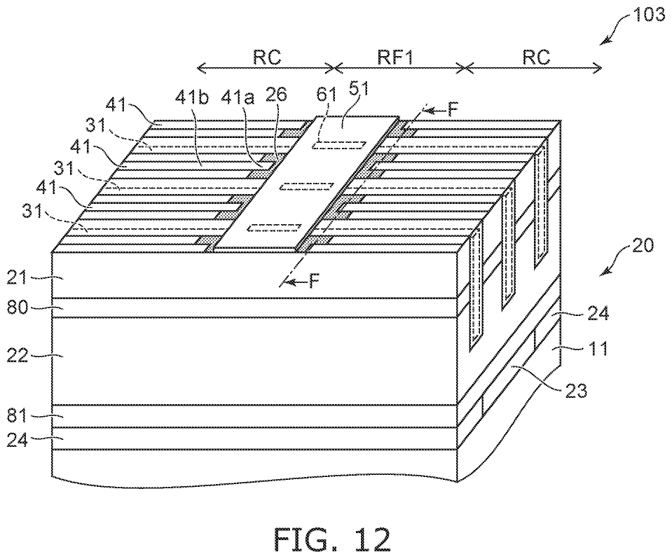

FIG. 12 is a schematic perspective view illustrating a semiconductor device according to the embodiment.

FIG. 12 illustrates the first interconnect region RF1 and the element regions RC in a semiconductor device 103 according to the embodiment. The semiconductor device 103 shown in FIG. 12 is different from the semiconductor device 100 shown in FIG. 1 and the like in arrangement of the fifth semiconductor region 25 and the sixth semiconductor region 26.

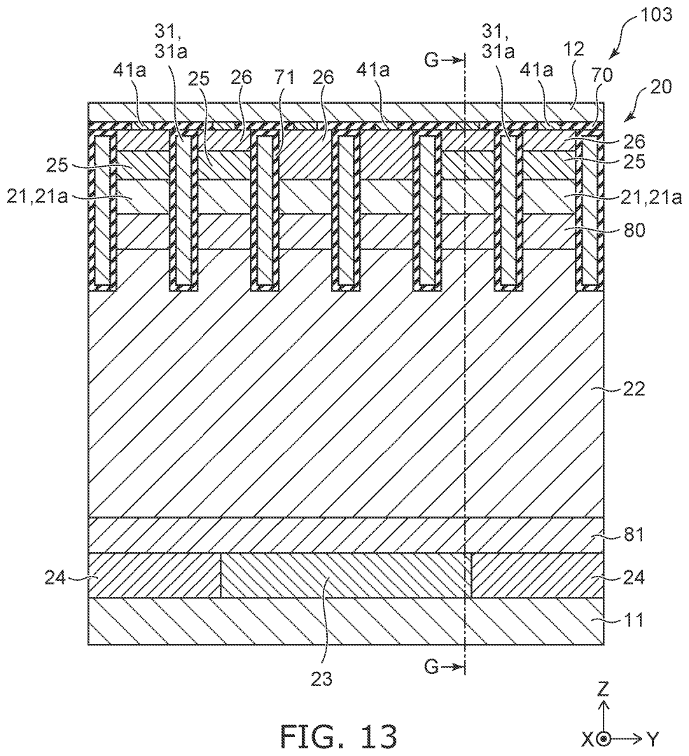

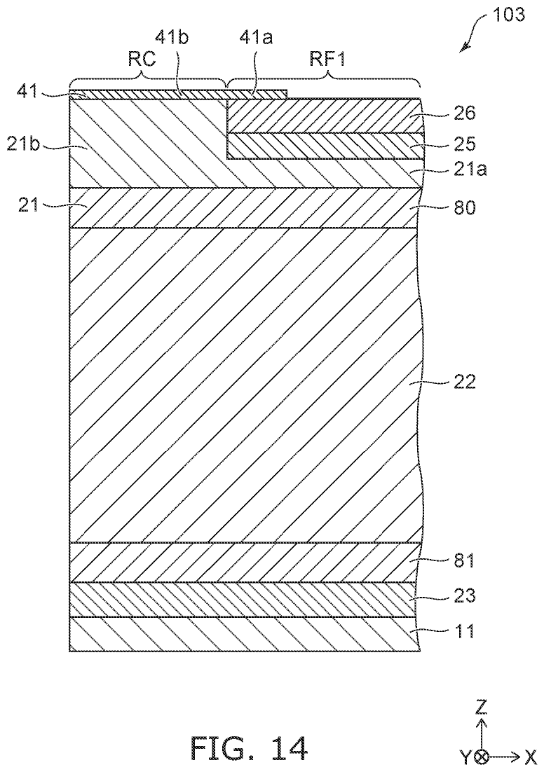

FIGS. 13 and 14 are schematic cross-sectional views illustrating the semiconductor device according to the embodiment.

FIG. 13 corresponds to a cross section taken along a line F-F shown in FIG. 12. FIG. 14 corresponds to a cross section taken along a line G-G shown in FIG. 13.

For example, as shown in FIG. 13, in the semiconductor device 103, the fifth semiconductor region 25 is between the sixth semiconductor region 26 and the first semiconductor region 21. For example, the fifth semiconductor region 25 is located immediately below at least a portion of the sixth semiconductor region 26. In this example, for example, the loss can also be reduced while preventing the operation of the parasitic thyristor.

The fifth semiconductor region 25 may not be provided on a surface of the semiconductor layer 20. The first contact portion 41 (the first contact region 41a) may be in contact with the sixth semiconductor region 26 and may not be in direct contact with the fifth semiconductor region 25. For example, as shown in FIG. 14, the fifth semiconductor region 25 is electrically connected to the first contact portion 41 via the second semiconductor portion 21b of the first semiconductor region 21. For example, in recovery of the diode operation, a hole current flows to the first contact portion 41 through the fifth semiconductor region 25 having a resistance lower than that of the first semiconductor portion 21a. Accordingly, for example, voltage drop in the first semiconductor portion 21a can be prevented, and the parasitic thyristor can be prevented from operating.

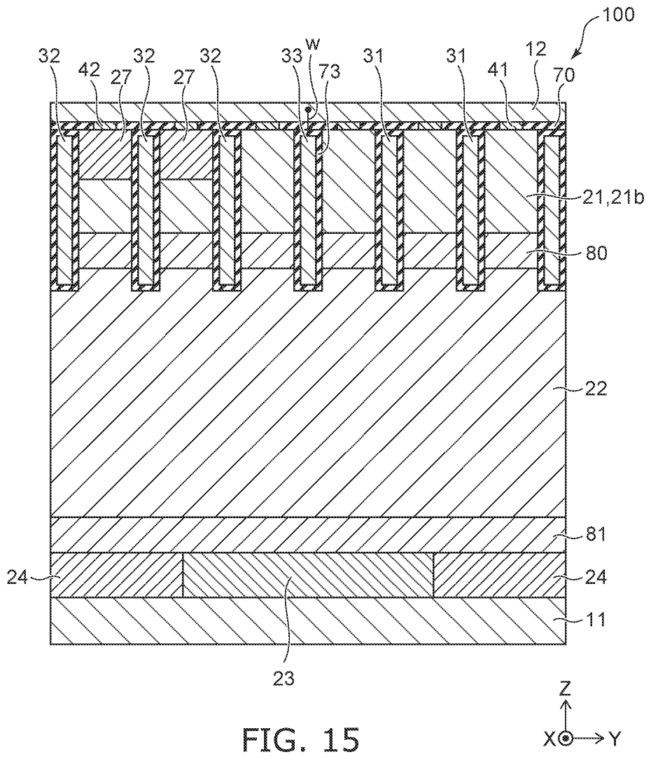

FIG. 15 is a schematic cross-sectional view illustrating the semiconductor device according to the embodiment.

FIG. 15 illustrates a cross section of a portion of the element region RC in the semiconductor device 100 according to the embodiment.

As shown in FIG. 15, the semiconductor device 100 may further include the conductive member 33. The conductive member 33 faces the first semiconductor region 21 and the second semiconductor region 22 via the third insulating portion 73. The conductive member 33 is aligned with the first semiconductor region 21 and the second semiconductor region 22 in a direction (for example, the Y-axis direction) intersecting the first direction. For example, the conductive member 33 is located between the first control electrode 31 and the second control electrode 32. For example, the conductive member 33 extends in the X-axis direction. Multiple conductive members 33 may be provided.

The third insulating portion 73 is in contact with the first semiconductor region 21, the second semiconductor region 22, and the conductive member 33. The conductive member 33 is insulated from the semiconductor layer 20 by the third insulating portion 73. The conductive member 33 is insulated from the first control electrode 31, the second control electrode 32, the first interconnect 51, and the second interconnect 52. The conductive member 33 is electrically connected to the second electrode 12 by an interconnect W. The conductive member 33 is, for example, a dummy electrode, and functions as a member for reducing electric field concentration.

As shown in FIG. 15, in the element region RC, the seventh semiconductor regions 27 of the second conductivity-type (n-type) are adjacent to the second control electrodes 32 (the second insulating portions 72) in the Y-axis direction. In the element region RC, a semiconductor region of the second conductivity-type may not be provided that is adjacent to the first control electrodes 31 (the first insulating portions 71) and the conductive member 33 (the third insulating portion 73) in the Y-axis direction.

FIG. 16 is a schematic circuit diagram illustrating a circuit using the semiconductor devices according to the embodiment.

As shown in FIG. 16, for example, a voltage Vcc, the first semiconductor device 100A, and the second semiconductor device 100B are connected in series. The first electrode 11 of the first semiconductor device 100A and the second electrode 12 of the second semiconductor device 100B are electrically connected. An inductance L is connected in parallel to the second semiconductor device 100B.

The first semiconductor device 100A performs, for example, the IGBT operation. In the first semiconductor device 100A, for example, a control described with reference to FIGS. 7A and 7B is performed. The second semiconductor device 100B performs, for example, the diode operation. In the second semiconductor device 100B, for example, a control described with reference to FIG. 7C is performed.

The embodiments may include the following configurations (for example, technical proposals).

### Configuration 1

A semiconductor device comprising:
a first electrode;
a second electrode, at least a portion of the second electrode being disposed in an element region, a direction from the first electrode toward the second electrode being along a first direction;
a first interconnect disposed in a first interconnect region, a direction from the element region toward the first interconnect region being along a second direction intersecting the first direction;
a semiconductor layer provided between the first electrode and the second electrode and between the first electrode and the first interconnect, the semiconductor layer including
   a first semiconductor region electrically connected to the second electrode, the first semiconductor region being of a first conductivity-type, a direction from the first electrode toward the first semiconductor region being along the first direction, the first semiconductor region including a first semiconductor portion disposed in the first interconnect region and a second semiconductor portion disposed in the element region,
   a second semiconductor region provided between the first electrode and the first semiconductor region, the second semiconductor region being of a second conductivity-type,
   a third semiconductor region provided between the first electrode and the second semiconductor region, the third semiconductor region being of the first conductivity-type,
   a fourth semiconductor region provided between the first electrode and the second semiconductor region, the fourth semiconductor region being of the second conductivity-type, an impurity concentration of the second conductivity-type in the fourth semiconductor region being higher than an impurity concentration of the second conductivity-type in the second semiconductor region,
   a fifth semiconductor region disposed in the first interconnect region, the fifth semiconductor region being electrically connected to the second electrode, the fifth semiconductor region being of the first conductivity-type, at least a portion of the first semiconductor portion being between the second semiconductor region and the fifth semiconductor region, an impurity concentration of the first conductivity-type in the fifth semiconductor region being higher than an impurity concentration of the first conductivity-type in the first semiconductor region,
   a sixth semiconductor region disposed in the first interconnect region, the sixth semiconductor region being electrically connected to the second electrode, the sixth semiconductor region being of the second conductivity-type, at least a portion of the first semiconductor portion being between the second semiconductor region and the sixth semiconductor region, and
   a seventh semiconductor region disposed in the element region, the seventh semiconductor region being electrically connected to the second electrode, the seventh semiconductor region being of the second conductivity-type, a portion of the second semiconductor portion being between the second semiconductor region and the seventh semiconductor region;
a first control electrode facing the first semiconductor region and the second semiconductor region via a first insulating portion, the first control electrode being arranged with the first semiconductor region and the second semiconductor region in a direction intersecting the first direction, the first control electrode including a first interconnect region portion disposed in the first interconnect region, the first interconnect region portion being electrically connected to the first interconnect; and
a second control electrode facing the first semiconductor region, the second semiconductor region, and the seventh semiconductor region via a second insulating portion, the second control electrode being arranged with the first semiconductor region, the second semiconductor region, and the seventh semiconductor region in a direction intersecting the first direction, the second control electrode being insulated from the first interconnect.

### Configuration 2

The device according to Configuration 1, further comprising:
a first contact region electrically connecting the second electrode and at least one of the fifth semiconductor region and the sixth semiconductor region in the first interconnect region; and
a second contact region electrically connecting the second electrode and the first semiconductor region in the element region.

### Configuration 3

The device according to Configuration 2, wherein
a plurality of the first contact regions are formed,
one of the plurality of first contact regions is in contact with the fifth semiconductor region and separated from the sixth semiconductor region, and
another one of the plurality of first contact regions is in contact with the sixth semiconductor region and separated from the fifth semiconductor region.

### Configuration 4

The device according to Configuration 2, wherein
the sixth semiconductor region is arranged with the fifth semiconductor region in the second direction, and
the first contact region is in contact with the fifth semiconductor region and the sixth semiconductor region.

### Configuration 5

The device according to Configuration 2, wherein
the sixth semiconductor region is arranged with the fifth semiconductor region in a direction intersecting the first direction and the second direction, and
the first contact region is in contact with the fifth semiconductor region and the sixth semiconductor region.

### Configuration 6

The device according to Configuration 2, wherein
the fifth semiconductor region is between the sixth semiconductor region and the first semiconductor region.

### Configuration 7

The device according to any one of Configurations 1 to 6, further comprising:
a second interconnect disposed in the second interconnect region,
a direction from the element region toward the second interconnect region being along the direction intersecting the first direction,
a portion of the semiconductor layer being provided between the first electrode and the second interconnect,
the second control electrode being electrically connected to the second interconnect in the second interconnect region, and
the first control electrode being insulated from the second interconnect.

### Configuration 8

The device according to Configuration 7, further comprising:
an eighth semiconductor region of the first conductivity-type, at least a portion of the eighth semiconductor region being disposed in the second interconnect region, the eighth semiconductor region being electrically connected to the second electrode, at least a portion of a third semiconductor portion of the first semiconductor region disposed in the second interconnect region being between the eighth semiconductor region and the second semiconductor region, an impurity concentration of the first conductivity-type in the eighth semiconductor region being higher than an impurity concentration of the first conductivity-type in the first semiconductor region.

### Configuration 9

The device according to Configuration 8, further comprising:
a third contact region electrically connecting the second electrode and the eighth semiconductor region in the second interconnect region; and
a fourth contact region electrically connecting the second electrode and the first semiconductor region in the element region and electrically connecting the second electrode and the seventh semiconductor region in the element region.

### Configuration 10

The device according to Configuration 9, wherein
the third contact region is not in contact with a semiconductor region of the second conductivity-type in the second interconnect region.

### Configuration 11

The device according to any one of Configurations 1 to 10, further comprising:
a first electrode pad electrically connected to the first control electrode and insulated from the second control electrode; and
a second electrode pad electrically connected to the second control electrode and insulated from the first control electrode.

### Configuration 12

The device according to any one of Configurations 1 to 11, further comprising:
a conductive member facing the first semiconductor region and the second semiconductor region via a third insulating portion and arranged with the first semiconductor region and the second semiconductor region in the direction intersecting the first direction, wherein
the conductive member is electrically connected to the second electrode in the element region.

### Configuration 13

The device according to any one of Configurations 1 to 12, wherein
the first control electrode extends in the second direction, and
the second control electrode extends in the second direction and is arranged with the first control electrode in a third direction perpendicular to the first direction and the second direction.

### Configuration 14

The device according to Configuration 13, wherein
a plurality of the first control electrodes are provided,
the plurality of first control electrodes are arranged in the third direction, and
the first interconnect extends in the third direction and is electrically connected to the plurality of first control electrodes.

### Configuration 15

The device according to any one of Configurations 1 to 14, wherein
the first control electrode is turned off before the second control electrode is turned off.

### Configuration 16

The device according to Configuration 15, wherein
a difference between a time when the second control electrode is turned off and a time when the first control electrode is turned off is 10 microseconds or more and 100 microseconds or less.

### Configuration 17

The device according to any one of Configurations 1 to 16, wherein
the first control electrode and the second control electrode are turned on when a current flows from the second electrode to the first electrode.

### Configuration 18

The device according to Configuration 17, wherein
duration of an on state of the first control electrode and the second control electrode is 10 microseconds or more and 100 microseconds or less.

### Configuration 19

The device according to Configuration 15, further comprising:
a control unit electrically connected to the first control electrode and the second control electrode, wherein
the control unit turns off the first control electrode before the second control electrode is turned off.

According to the embodiments, a semiconductor device can be provided in which a loss can be reduced.

In this specification, being “electrically connected” includes not only the case of being connected in direct contact, but also the case of being connected via another conductive member, etc.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode, at least a portion of the second electrode being disposed in an element region, a direction from the first electrode toward the second electrode being along a first direction;
a first interconnect disposed in a first interconnect region, a direction from the element region toward the first interconnect region being along a second direction intersecting the first direction;
a semiconductor layer provided between the first electrode and the second electrode and between the first electrode and the first interconnect, the semiconductor layer including
a first semiconductor region electrically connected to the second electrode, the first semiconductor region being of a first conductivity-type, a direction from the first electrode toward the first semiconductor region being along the first direction, the first semiconductor region including a first semiconductor portion disposed in the first interconnect region and a second semiconductor portion disposed in the element region,
a second semiconductor region provided between the first electrode and the first semiconductor region, the second semiconductor region being of a second conductivity-type,
a third semiconductor region provided between the first electrode and the second semiconductor region, the third semiconductor region being of the first conductivity-type,
a fourth semiconductor region provided between the first electrode and the second semiconductor region, the fourth semiconductor region being of the second conductivity-type, an impurity concentration of the second conductivity-type in the fourth semiconductor region being higher than an impurity concentration of the second conductivity-type in the second semiconductor region,
a fifth semiconductor region disposed in the first interconnect region, the fifth semiconductor region being electrically connected to the second electrode, the fifth semiconductor region being of the first conductivity-type, at least a portion of the first semiconductor portion being between the second semiconductor region and the fifth semiconductor region, an impurity concentration of the first conductivity-type in the fifth semiconductor region being higher than an impurity concentration of the first conductivity-type in the first semiconductor region,
a sixth semiconductor region disposed in the first interconnect region, the sixth semiconductor region being electrically connected to the second electrode, the sixth semiconductor region being of the second conductivity-type, at least a portion of the first semiconductor portion being between the second semiconductor region and the sixth semiconductor region, and
a seventh semiconductor region disposed in the element region, the seventh semiconductor region being electrically connected to the second electrode, the seventh semiconductor region being of the second conductivity-type, a portion of the second semiconductor portion being between the second semiconductor region and the seventh semiconductor region;
a first control electrode facing the first semiconductor region and the second semiconductor region via a first insulating portion, the first control electrode being arranged with the first semiconductor region and the second semiconductor region in a direction intersecting the first direction, the first control electrode including a first interconnect region portion disposed in the first interconnect region, the first interconnect region portion being electrically connected to the first interconnect; and
a second control electrode facing the first semiconductor region, the second semiconductor region, and the seventh semiconductor region via a second insulating portion, the second control electrode being arranged with the first semiconductor region, the second semiconductor region, and the seventh semiconductor region in a direction intersecting the first direction, the second control electrode being insulated from the first interconnect.

2. The device according to claim 1, further comprising:
a first contact region electrically connecting the second electrode and at least one of the fifth semiconductor region and the sixth semiconductor region in the first interconnect region; and
a second contact region electrically connecting the second electrode and the first semiconductor region in the element region.

3. The device according to claim 2, wherein
a plurality of the first contact regions are formed,
one of the plurality of first contact regions is in contact with the fifth semiconductor region and separated from the sixth semiconductor region, and
another one of the plurality of first contact regions is in contact with the sixth semiconductor region and separated from the fifth semiconductor region.

4. The device according to claim 2, wherein
the sixth semiconductor region is arranged with the fifth semiconductor region in the second direction, and
the first contact region is in contact with the fifth semiconductor region and the sixth semiconductor region.

5. The device according to claim 2, wherein
the sixth semiconductor region is arranged with the fifth semiconductor region in a direction intersecting the first direction and the second direction, and
the first contact region is in contact with the fifth semiconductor region and the sixth semiconductor region.

6. The device according to claim 2, wherein
the fifth semiconductor region is between the sixth semiconductor region and the first semiconductor region.

7. The device according to claim 1, further comprising:
a second interconnect disposed in the second interconnect region,
a direction from the element region toward the second interconnect region being along the direction intersecting the first direction,
a portion of the semiconductor layer being provided between the first electrode and the second interconnect,
the second control electrode being electrically connected to the second interconnect in the second interconnect region, and
the first control electrode being insulated from the second interconnect.

8. The device according to claim 7, further comprising:
an eighth semiconductor region of the first conductivity-type, at least a portion of the eighth semiconductor region being disposed in the second interconnect region, the eighth semiconductor region being electrically connected to the second electrode, at least a portion of a third semiconductor portion of the first semiconductor region disposed in the second interconnect region being between the eighth semiconductor region and the second semiconductor region, an impurity concentration of the first conductivity-type in the eighth semiconductor region being higher than an impurity concentration of the first conductivity-type in the first semiconductor region.

9. The device according to claim 8, further comprising:
a third contact region electrically connecting the second electrode and the eighth semiconductor region in the second interconnect region; and
a fourth contact region electrically connecting the second electrode and the first semiconductor region in the element region and electrically connecting the second electrode and the seventh semiconductor region in the element region.

10. The device according to claim 9, wherein
the third contact region is not in contact with a semiconductor region of the second conductivity-type in the second interconnect region.

11. The device according to claim 1, further comprising:
a first electrode pad electrically connected to the first control electrode and insulated from the second control electrode; and
a second electrode pad electrically connected to the second control electrode and insulated from the first control electrode.

12. The device according to claim 1, further comprising:
a conductive member facing the first semiconductor region and the second semiconductor region via a third insulating portion and arranged with the first semiconductor region and the second semiconductor region in the direction intersecting the first direction, wherein
the conductive member is electrically connected to the second electrode in the element region.

13. The device according to claim 1, wherein
the first control electrode extends in the second direction, and
the second control electrode extends in the second direction and is arranged with the first control electrode in a third direction perpendicular to the first direction and the second direction.

14. The device according to claim 13, wherein
a plurality of the first control electrodes are provided,
the plurality of first control electrodes are arranged in the third direction, and
the first interconnect extends in the third direction and is electrically connected to the plurality of first control electrodes.

15. The device according to claim 1, wherein
the first control electrode is turned off before the second control electrode is turned off.

16. The device according to claim 15, wherein
a difference between a time when the second control electrode is turned off and a time when the first control electrode is turned off is 10 microseconds or more and 100 microseconds or less.

17. The device according to claim 1, wherein
the first control electrode and the second control electrode are turned on when a current flows from the second electrode to the first electrode.

18. The device according to claim 17, wherein
duration of an on state of the first control electrode and the second control electrode is 10 microseconds or more and 100 microseconds or less.

19. The device according to claim 15, further comprising:
a control unit electrically connected to the first control electrode and the second control electrode, wherein
the control unit turns off the first control electrode before the second control electrode is turned off.
